(19) United States
(12) Patent Application Publication
(10) Pub. No.: US 2025/0331405 A1
(43) Pub. Date: Oct. 23, 2025

(54) DISPLAY DEVICE

(71) Applicant: Samsung Display Co., LTD., Yongin-si (KR)

(72) Inventors: Ki Cheol SONG, Yongin-si (KR); Yeon Joo SEO, Yongin-si (KR); Chang Woo LEE, Yongin-si (KR)

(73) Assignee: Samsung Display Co., LTD., Yongin-si (KR)

(21) Appl. No.: 18/962,053

(22) Filed: Nov. 27, 2024

(30) Foreign Application Priority Data
Apr. 17, 2024 (KR) 10-2024-0051487

(51) Int. Cl. H10K 59/80; C09J 7/38; C09J 11/04; C09J 11/06; C09J 11/08; H10K 59/40

(52) U.S. Cl. CPC H10K 59/879; C09J 7/385; C09J 11/04; C09J 11/06; C09J 11/08; H10K 59/873; C09J 2203/326; C09J 2301/408; H10K 59/40

(57) ABSTRACT

A display device includes a display panel including a light emitting element, a low refractive pattern disposed on the display panel and including an opening overlapping the light emitting element in a thickness direction of the display panel, and a high refractive adhesive layer disposed on the low refractive pattern and the display panel and including inorganic particles. The high refractive adhesive layer includes 1 wt % to 3 wt % of the inorganic particles based on a total weight of the high refractive adhesive layer.

### CROSS-REFERENCE TO RELATED APPLICATION(S)

This application claims priority to and benefits of Korean Patent Application No. 10-2024-0051487 under 35 U.S.C. 119, filed on Apr. 17, 2024, in the Korean Intellectual Property Office (KIPO), the entire contents of which are incorporated herein by reference.

### BACKGROUND

### 1. Technical Field

The disclosure relates to a display device.

### 2. Description of the Related Art

As the information society develops, the demand for display devices for displaying images has increased and diversified. For example, display devices have been applied to various electronic devices such as smartphones, digital cameras, laptop computers, navigation devices, and smart televisions. The display devices may be flat panel display devices such as liquid crystal display devices, field emission display devices, or organic light emitting display devices.

Recently, foldable display devices have got a lot of attention. The foldable display devices have advantages of both smartphones and tablet PCs because they may have good portability and wide screens.

### SUMMARY

Aspects of the disclosure provide a display device including an adhesive layer having flexibility and durability so as to be capable of being applied to a foldable display device, and a composition for the adhesive layer.

However, aspects of the disclosure are not restricted to those set forth herein. The above and other aspects of the disclosure will become more apparent to one of ordinary skill in the art to which the disclosure pertains by referencing the detailed description of the disclosure given below.

A display device according to an embodiment may include a display panel including a light emitting element, a low refractive pattern disposed on the display panel and including an opening overlapping the light emitting element in a thickness direction of the display panel, and a high refractive adhesive layer disposed on the low refractive pattern and the display panel and including inorganic particles. The high refractive adhesive layer may include 1 wt % to 3 wt % of the inorganic particles based on a total weight of the high refractive adhesive layer.

According to an embodiment, the display device may further include a polarizing film disposed on the high refractive adhesive layer.

According to an embodiment, the high refractive adhesive layer may be in contact with the polarizing film.

According to an embodiment, the low refractive pattern may have a refractive index in a range of about 1.45 to about 1.55, and the high refractive adhesive layer may have a refractive index in a range of about 1.55 to about 1.65.

According to an embodiment, the inorganic particles may be at least one of zirconium oxide (ZrO₂), titanium oxide (TiO₂), aluminum oxide (Al₂O₃), and silicon oxide (SiO₂).

According to an embodiment, the inorganic particles may be dispersed in the high refractive adhesive layer.

According to an embodiment, the high refractive adhesive layer may further include an aromatic monomer and an aliphatic monomer.

According to an embodiment, the aromatic monomer may include a first aromatic monomer and a second aromatic monomer different from each other.

According to an embodiment, the aliphatic monomer may include a first aliphatic monomer, a second aliphatic monomer, and a third aliphatic monomer different from each other.

According to an embodiment, the high refractive adhesive layer may further include a xylene resin and a sulfide aromatic compound.

According to an embodiment, the high refractive adhesive layer may include about 40 wt % to about 80 wt % of the aromatic monomer, about 10 wt % to about 30 wt % of the aliphatic monomer, about 10 wt % to about 25 wt % of the xylene resin, about 10 wt % to about 20 wt % of the sulfide aromatic compound, and about 1 wt % to about 3 wt % of the inorganic particles based on the total weight of the high refractive adhesive layer.

According to an embodiment, the high refractive adhesive layer may have a storage modulus in a range of about 1.0 MPa to about 10 MPa at −20° C., the high refractive adhesive layer may have a loss modulus in a range of about 3.5 MPa to about 10 MPa at −20° C., and the high refractive adhesive layer may have a viscoelastic ratio in a range of about 2.9 to about 6 at −20° C.

According to an embodiment, the high refractive adhesive layer may have a glass transition temperature (Tg) in a range of about −30° C. to about −10° C.

According to an embodiment, the high refractive adhesive layer may have a creep value in a range of about 10% to about 40% at 60° C.

According to an embodiment, the high refractive adhesive layer may have a recovery value of greater than or equal to about 70% at −20° C.

According to an embodiment, the display device may further include a touch sensor layer disposed between the display panel and the low refractive pattern. The high refractive adhesive layer may be in contact with the touch sensor layer and the polarizing film.

According to an embodiment, the low refractive pattern may have a tapered shape in a cross-sectional view.

A composition for an adhesive layer according to an embodiment may include a first aromatic monomer and a second aromatic monomer different from each other, a first aliphatic monomer, a second aliphatic monomer, and a third aliphatic monomer different from each other, and inorganic particles including at least one of zirconium oxide (ZrO₂), titanium oxide (TiO₂), aluminum oxide (Al₂O₃), and silicon oxide (SiO₂) The inorganic particles may be included in an amount of 1 wt % to 3 wt % based on a total weight of the composition for the adhesive layer.

According to an embodiment, a molecular weight of the first aromatic monomer may be less than a molecular weight of the second aromatic monomer, a content of the first aromatic monomer may be higher than a content of the second aromatic monomer, a molecular weight of the first aliphatic monomer may be greater than a molecular weight of the second aliphatic monomer and a molecular weight of the third aliphatic monomer, the molecular weight of the second aliphatic monomer may be greater than the molecular weight of the third aliphatic monomer, a content of the first aliphatic monomer may be higher than a content of the second aliphatic monomer and a content of the third aliphatic monomer, and the content of the second aliphatic monomer may be higher than the content of the third aliphatic monomer.

According to an embodiment, the composition for an adhesive layer may further include a xylene resin and a sulfide aromatic compound.

According to an embodiment, an electronic device may include a display device including a display panel including a light emitting element; a low refractive pattern disposed on the display panel and including an opening overlapping the light emitting element in a thickness direction of the display panel; and a high refractive adhesive layer disposed on the low refractive pattern and the display panel and including inorganic particles, wherein the high refractive adhesive layer may include 1 wt % to 3 wt % of the inorganic particles based on a total weight of the high refractive adhesive layer.

Detailed contents of other embodiments are described in a detailed description and are illustrated in the drawings.

A display device according to an embodiment may not include a separate adhesive layer between a display panel and a front stacked structure, and may bond the display panel and the front stacked structure to each other through a high refractive adhesive layer of the display panel. The high refractive adhesive layer including a low content of inorganic particles may have excellent flexibility and durability in a foldable display device.

The effects of the disclosure are not limited to the aforementioned effects, and various other effects are included in the specification.

### BRIEF DESCRIPTION OF THE DRAWINGS

The above and other aspects and features of the disclosure will become more apparent by describing in detail embodiments thereof with reference to the attached drawings, in which:

FIG. 1 is a perspective view illustrating an unfolded state of a display device according to an embodiment;

FIG. 2 is a perspective view illustrating a folded state of the display device according to an embodiment;

FIG. 3 is a perspective view illustrating an unfolded state of a display device according to an embodiment;

FIG. 4 is a perspective view illustrating a folded state of the display device according to an embodiment;

FIG. 5 is an exploded perspective view of the display device according to an embodiment of FIG. 1;

FIG. 6 is a schematic cross-sectional view of the display device according to an embodiment taken along line I-I′ of FIG. 5;

FIG. 7 is an enlarged schematic cross-sectional view of area A of FIG. 6;

FIG. 8 is a plan view illustrating a touch sensor layer of the display device according to an embodiment;

FIG. 9 is a schematic cross-sectional view of the display device according to an embodiment taken along line II-II′ of FIG. 8; and

FIG. 10 is an enlarged schematic cross-sectional view of area B of FIG. 9.

### DETAILED DESCRIPTION OF THE EMBODIMENTS

Advantages and features of the disclosure and methods for accomplishing these advantages and features will become apparent from embodiments to be described later in detail with reference to the accompanying drawings. However, the disclosure is not limited to embodiments disclosed below, and may be implemented in various different forms, these embodiments will be provided only in order to make the disclosure complete and allow one of ordinary skill in the art to which the disclosure pertains to completely recognize the scope of the disclosure, and the disclosure will be defined by the scope of the claims.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element. Throughout the specification, the same components will be denoted by the same reference numerals. Shapes, sizes, proportions, angles, the numbers, and the like, disclosed in the drawings for describing embodiments are illustrative, and thus, the disclosure is not limited to those illustrated in the drawings.

The terms “first”, “second”, and the like are used to describe various components, but these components are not limited by these terms. These terms are used only in order to distinguish one component from other components. Accordingly, a first component mentioned below may be a second component within the technical spirit of the disclosure.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, specific embodiments will be described with reference to the accompanying drawings.

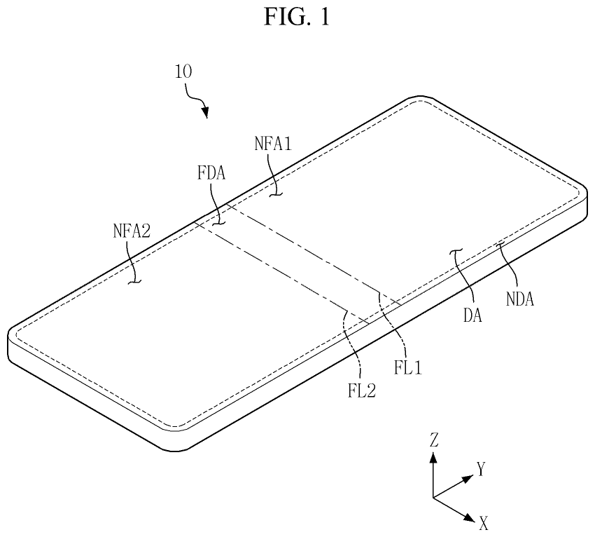

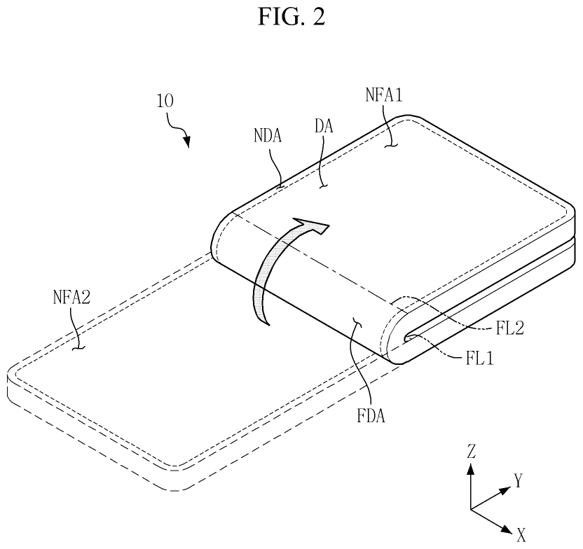

FIGS. 1 and 2 are perspective views illustrating a display device 10 according to an embodiment. FIG. 1 is a perspective view illustrating an unfolded state of a display device 10 according to an embodiment. FIG. 2 is a perspective view illustrating a folded state of the display device 10 according to an embodiment.

In FIGS. 1 and 2, a first direction (X-axis direction) may be a direction parallel to a side of the display device 10 in a plan view, and may be, for example, a transverse direction of the display device 10. A second direction (Y-axis direction) may be a direction parallel to another side of the display device 10 in contact with the side of the display device 10 in a plan view, and may be a longitudinal direction of the display device 10. A third direction (Z-axis direction) may be a thickness direction of the display device 10.

The display device 10 may be used as an electronic device. An electronic device including the display device 10 may include the display screen of portable electronic devices such as a mobile phone, a smart phone, a tablet PC, a smart watch, a watch phone, a mobile communications terminal, an electronic notebook, an electronic book, a portable multimedia player (PMP), a navigation device and a ultra mobile PC (UMPC), a television, a notebook, a monitor, a billboard and the Internet of Things (IoT). Those listed-above are merely as examples, and the display device 10 may be employed in other electronic devices as well.

The display device 10 may have a rectangular or square shape in a plan view. The display device 10 may have a rectangular shape with vertical corners or a rectangular shape with rounded corners in a plan view. The display device 10 may include two short sides extending in the first direction (X-axis direction) and two long sides extending in the second direction (Y-axis direction) in a plan view.

The display device 10 may include a display area DA and a non-display area NDA. In a plan view, a shape of the display area DA may correspond to the shape of the display device 10. For example, in case that the display device 10 has a rectangular shape in a plan view, the display area DA may also have a rectangular shape.

The display area DA may be an area displaying an image by including multiple pixels. The pixels may be arranged in a matrix direction. The pixels may have a rectangular shape, a rhombic shape, or a square shape in a plan view, but are not limited thereto. For example, the pixels may have other quadrangular shapes other than the rectangular shape, the rhombic shape, or the square shape, other polygonal shapes other than a quadrangular shape, a circular shape, or an elliptical shape in a plan view.

The non-display area NDA may be an area that does not display an image because it does not include pixels. The non-display area NDA may be disposed adjacent to the display area DA. The non-display area NDA may surround the display area DA as illustrated in FIGS. 1 and 2, but is not limited thereto. In another embodiment, the display area DA may be partially surrounded by the non-display area NDA.

The display device 10 may be maintained in a folded state or an unfolded state. The display device 10 may be folded in an in-folding manner in which the display area DA is disposed inside as illustrated in FIG. 2. In case that the display device 10 is folded in the in-folding manner, front surfaces of the display device 10 may face each other. In another embodiment, the display device 10 may be folded in an out-folding manner in which the display area DA is disposed outside. In case that the display device 10 is folded in the out-folding manner, rear surfaces of the display device 10 may face each other.

The display device 10 may include a folding area FDA, a first non-folding area NFA1, and a second non-folding area NFA2. The folding area FDA may be an area where the display device 10 is bendable or foldable, and the first non-folding area NFA1 and the second non-folding area NFA2 may be areas where the display device 10 is not bendable or foldable.

The first non-folding area NFA1 may be disposed on a side, for example, the upper side, of the folding area FDA. The second non-folding area NFA2 may be disposed on another side, for example, the lower side, of the folding area FDA. The folding area FDA may be an area defined by a first folding line FL1 and a second folding line FL2, and may be an area bendable with a curvature. The first folding line FL1 may be a boundary between the folding area FDA and the first non-folding area NFA1, and the second folding line FL2 may be a boundary between the folding area FDA and the second non-folding area NFA2.

The first folding line FL1 and the second folding line FL2 may extend in the first direction (X-axis direction) as illustrated in FIGS. 1 and 2, and the display device 10 may be foldable about the second direction (Y-axis direction). For this reason, a length of the display device 10 in the second direction (Y-axis direction) may be reduced by approximately half, and thus, a user may conveniently carry the display device 10.

In case that the first folding line FL1 and the second folding line FL2 extend in the first direction (X-axis direction) as illustrated in FIGS. 1 and 2, a length of the folding area FDA in the second direction (Y-axis direction) may be smaller than a length of the folding area FDA in the first direction (X-axis direction). A length of the first non-folding area NFA1 in the second direction (Y-axis direction) may be greater than a length of the first non-folding area NFA1 in the first direction (X-axis direction). A length of the second non-folding area NFA2 in the second direction (Y-axis direction) may be greater than a length of the second non-folding area NFA2 in the first direction (X-axis direction).

Each of the display area DA and the non-display area NDA may overlap at least one of the folding area FDA, the first non-folding area NFA1, and the second non-folding area NFA2 in a plan view. It has been illustrated in FIGS. 1 and 2 that each of the display area DA and the non-display area NDA overlaps the folding area FDA, the first non-folding area NFA1, and the second non-folding area NFA2 in a plan view.

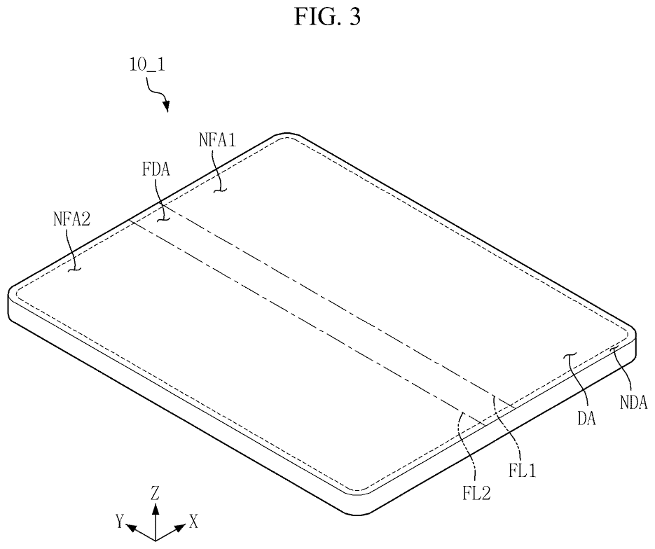

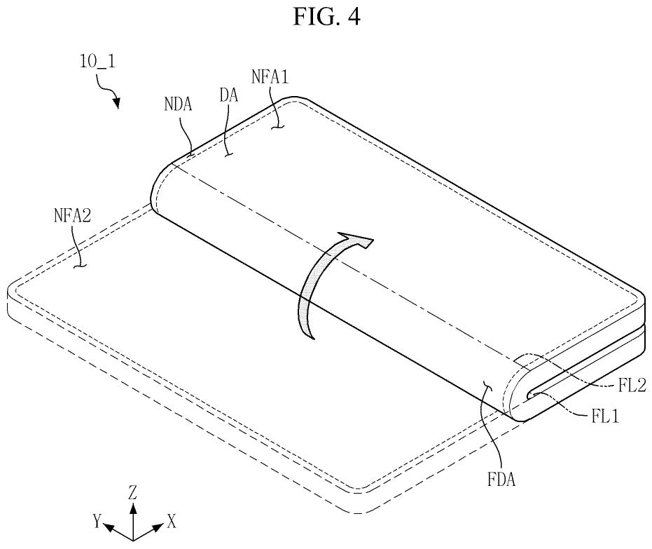

FIGS. 3 and 4 are perspective views illustrating a display device 10_1 according to an embodiment. FIG. 3 is a perspective view illustrating an unfolded state of a display device 10_1 according to an embodiment. FIG. 4 is a perspective view illustrating a folded state of the display device 10_1 according to an embodiment.

An embodiment of FIGS. 3 and 4 may be different from an embodiment of FIGS. 1 and 2 at least in that a first folding line FL1 and a second folding line FL2 may extend in the second direction (Y-axis direction), and the display device 10_1 may be foldable in the first direction (X-axis direction), and thus, a length of the display device 10_1 in the first direction (X-axis direction) may be reduced by approximately half, and accordingly, a user may conveniently carry the display device 10_1. Therefore, a description of an embodiment of FIGS. 3 and 4 is omitted.

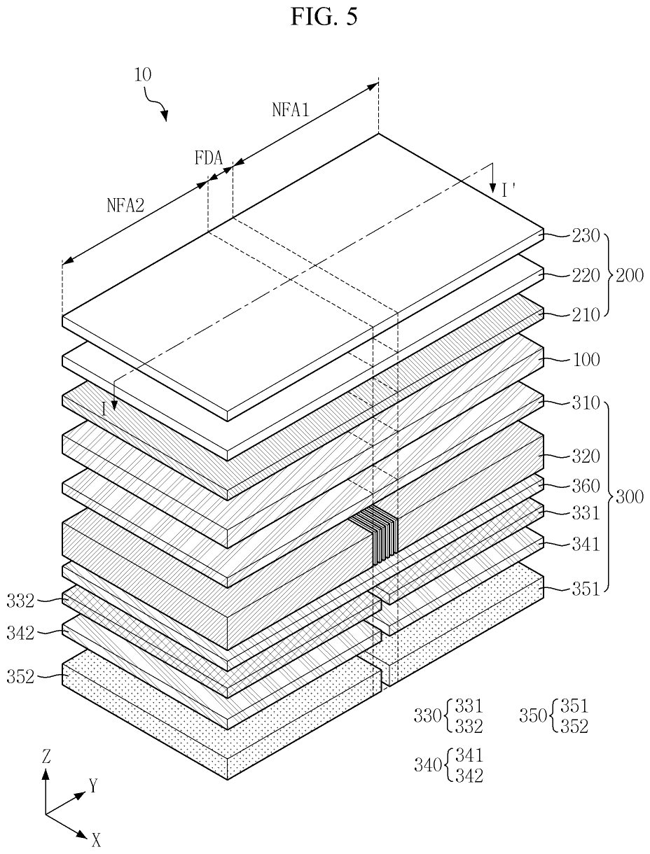

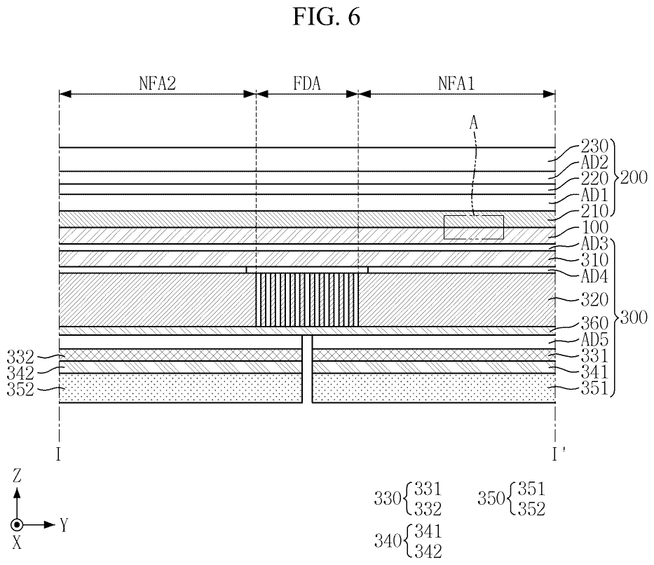

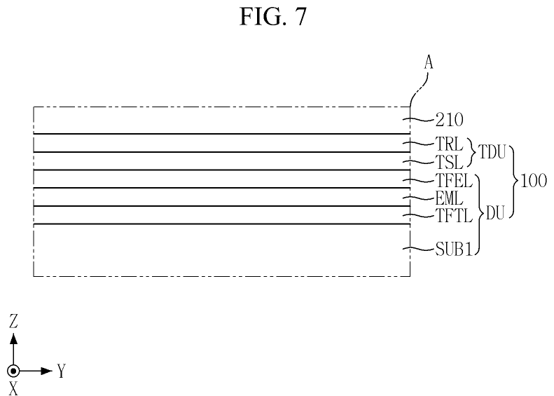

FIG. 5 is an exploded perspective view of the display device according to an embodiment of FIG. 1. FIG. 6 is a schematic cross-sectional view of the display device according to an embodiment taken along line I-I′ of FIG. 5. FIG. 7 is an enlarged view of area A of FIG. 6.

Referring to FIGS. 5 and 6, the display device 10 may include a display panel 100, a front stacked structure 200 stacked in front of the display panel 100, and a rear stacked structure 300 stacked behind the display panel 100. The front of the display panel 100 may be a direction in which the display panel 100 displays a screen, and the rear of the display panel 100 may be a direction opposite to the front of the display panel 100. A surface of the display panel 100 may be positioned at the front, and another surface of the display panel 100 may be positioned at the rear.

The front stacked structure 200 may include a polarizing film 210, a window 220, and a protective film 230, and the rear stacked structure 300 may include a panel lower member 310, a light blocking member 320, a digitizer layer 330, a shielding member 340, a heat dissipation member 350, and a buffer member 360.

The front stacked structure 200 may further include a first adhesive member AD1 disposed between the polarizing film 210 and the window 220 and a second adhesive member AD2 disposed between the window 220 and the protective film 230. The rear stacked structure 300 may further include a third adhesive member AD3 disposed between the display panel 100 and the panel lower member 310, a fourth adhesive member AD4 disposed between the panel lower member 310 and the light blocking member 320, and a fifth adhesive member AD5 disposed between the buffer member 360 and the digitizer layer 330.

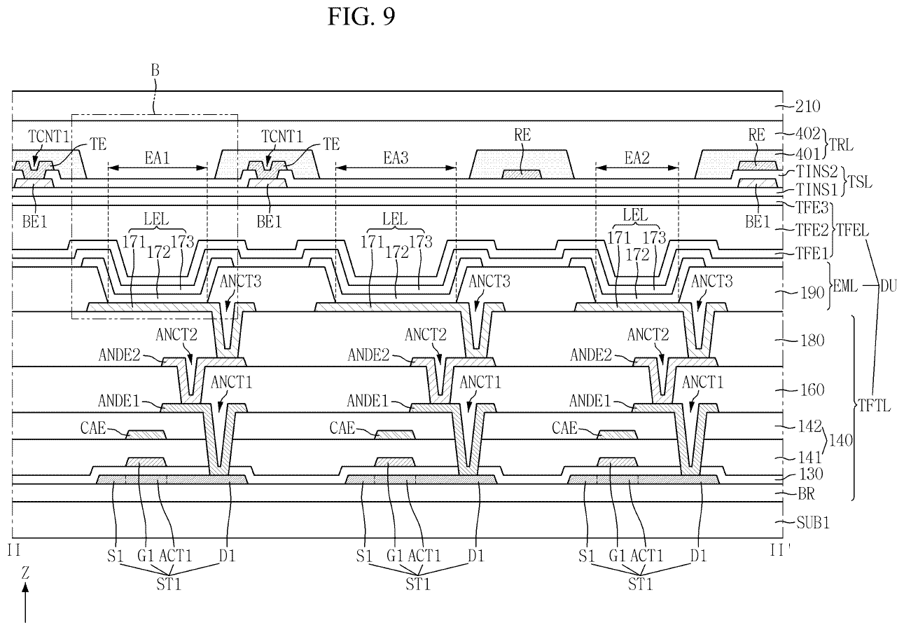

Examples of display panels displaying images may include an organic light emitting display panel using organic light emitting diodes, a quantum dot light emitting display panel including quantum dot light emitting layers, an inorganic light emitting display panel including inorganic semiconductors, and a micro light emitting display panel using micro light emitting diodes (micro LEDs). Hereinafter, it will be described that the display panel 100 is an organic light emitting display panel according to an embodiment, but the disclosure is not limited thereto. The display panel 100 will be described in detail later with reference to FIG. 9.

The polarizing film 210 may be disposed on a front surface of the display panel 100. The polarizing film 210 may be attached to the front surface of the display panel 100 by a high refraction adhesive layer 402 of the display panel 100 to be described below. The polarizing film 210 may include a linear polarizing plate and a phase retardation film such as a λ/4 plate (quarter-wave plate).

The window 220 may be disposed on a front surface of the polarizing film 210. The window 220 may be attached to the front surface of the polarizing film 210 by the first adhesive member AD1. The window member 220 may be made of a transparent material, and may include, for example, glass or a plastic. For example, the window 220 may be ultra-thin glass (UTG) having a thickness of less than or equal to about 0.1 mm or a transparent polyimide film, but is not limited thereto.

The protective film 230 may be disposed on a front surface of the window 220. The protective film 230 may be attached to the front surface of the window 220 by the second adhesive member AD2. The protective member 230 may perform at least one of a scattering prevention function of the window 220, a shock absorption function, a chopping prevention function, a fingerprint prevention function, and a glare prevention function.

The first adhesive member AD1 and the second adhesive member AD2 may be the same as or different from each other, and may each be a transparent pressure sensitive adhesive (PSA), an optically clear adhesive (OCA) film, or an optically clear resin (OCR).

The panel lower member 310 may be disposed on a rear surface of the display panel 100. The panel lower member 310 may be attached to the rear surface of the display panel 100 by the third adhesive member AD3. The third adhesive member AD3 may be a pressure sensitive adhesive (PSA). The panel lower member 310 may be a buffer layer for absorbing an external shock. The panel lower member 310 may absorb the external shock to prevent the display panel 100 from being damaged. The panel lower member 310 may be formed as a single layer or multiple layers. For example, the panel lower member 310 may include an elastic material such as a sponge formed by foam-molding rubber, a urethane-based material, or an acrylic material.

It has been illustrated in FIGS. 5 and 6 that the panel lower member 310 is disposed in the folding area FDA, but the disclosure is not limited thereto. For example, a portion of the panel lower member 310 in the folding area FDA may be removed so as for the display device 10 to be readily foldable.

The light blocking member 320 may be disposed on a rear surface of the panel lower member 310. The light blocking member 320 may be attached to the rear surface of the panel lower member 310 by the fourth adhesive member AD4. The fourth adhesive member AD4 may not be disposed in the folding area FDA in order to reduce folding stress of the display device 10. For example, multiple fourth adhesive members AD4 may be provided, one of the fourth adhesive members AD4 may be disposed in the first non-folding area NFA1, and another one of the fourth adhesive members AD4 may be disposed in the second non-folding area NFA2. The fourth adhesive members AD4 may each be a pressure sensitive adhesive.

The light blocking member 320 may include a polymer including carbon fiber or glass fiber. In case that the light blocking member 320 includes carbon fiber, the polymer may be epoxy, polyester, polyamide, polycarbonate, polypropylene, polybutylene, or vinyl ester. In case that the light blocking member 320 includes glass fiber, the polymer may be epoxy, polyester, polyamide, or vinyl ester.

A thickness of the light blocking member 320 may be greater than a thickness of the digitizer layer 330 or a thickness of the shielding member 340. The thickness of the light blocking member 320 may be greater than a thickness of the display panel 100.

The light blocking member 320 may include multiple bars disposed in the folding area FDA so as to be readily bendable in the folding area FDA. An extension direction of each of the bars, an extension direction of the first folding line FL1, and an extension direction of the second folding line FL2 may be substantially parallel to each other. For example, each of the bars may extend in the first direction (X-axis direction). The bars may be arranged in the second direction (Y-axis direction). Slits may be formed between bars adjacent to each other among the bars. A width of each of the bars may be smaller than a width of each of the slits.

The buffer member 360 may be disposed on a rear surface of the light blocking member 320. The buffer member 360 may absorb an external shock to prevent the light blocking member 320 and the digitizer layer 330 from being damaged. The buffer member 360 may include an elastic material such as a sponge formed by foam-molding rubber, a urethane-based material, or an acrylic material.

The digitizer layer 330 may include a first digitizer layer 331 and a second digitizer layer 332. The first digitizer layer 331 and the second digitizer layer 332 may be disposed on a rear surface of the buffer member 360. The first digitizer layer 331 and the second digitizer layer 332 may be attached to the rear surface of the buffer member 360 by the fifth adhesive members AD5. The fifth adhesive members AD5 may each be a pressure sensitive adhesive.

The first digitizer layer 331, the second digitizer layer 332, and the fifth adhesive members AD5 may not be disposed in at least a portion of the folding area FDA in order to reduce the folding stress of the display device 10. For example, one of the fifth adhesive members AD5 and the first digitizer layer 331 may be disposed in the first non-folding area NFA1, and another one of the fifth adhesive members AD5 and the second digitizer 332 may be disposed in the second non-folded area NFA2. A gap between the first digitizer layer 331 and the second digitizer layer 332 may overlap the folding area FDA in the thickness direction (Z-axis direction), and may be smaller than a width of the folding area FDA. The width of the folding area FDA may be a length of the folding area FDA in the second direction DR2.

The first digitizer layer 331 and the second digitizer layer 332 may include electrode patterns for sensing approach or contact of an electronic pen such as a stylus pen supporting electromagnetic resonance (EMR). The first digitizer layer 331 and the second digitizer layer 332 may sense magnetic fields or electromagnetic signals emitted from the electronic pen by the electrode patterns, and decide a point where the sensed magnetic field or electromagnetic signal is the greatest as touch coordinates.

The shielding member 340 may include a first shielding member 341 and a second shielding member 342. The first shielding member 341 and the second shielding member 342 may be disposed on a rear surface of the digitizer layer 330.

The first shielding member 341 and the second shielding member 342 may not be disposed in at least a portion of the folding area FDA in order to reduce the folding stress of the display device 10. For example, the first shielding member 341 may be disposed in the first non-folding area NFA1, and the second shielding member 342 may be disposed in the second non-folding area NFA2. A gap between the first shielding member 341 and the second shielding member 342 may overlap the folding area FDA in the thickness direction (Z-axis direction), and may be smaller than the width of the folding area FDA.

The first shielding member 341 and the second shielding member 342 may include magnetic metal powders, and thus, the magnetic fields or the electromagnetic signals passing through the digitizer layer 330 may flow into the first shielding member 341 and the second shielding member 342. The first shielding member 341 and the second shielding member 342 may reduce the magnetic fields or the electromagnetic signals emitted to rear surfaces of the first shielding member 341 and the second shielding member 342.

The heat dissipation member 350 may include a first heat dissipation member 351 and a second heat dissipation member 352. The first heat dissipation member 351 and the second heat dissipation member 352 may be disposed on a rear surface of the shielding member 340.

The first heat dissipation member 351 and the second heat dissipation member 352 may not be disposed in at least a portion of the folding area FDA in order to reduce the folding stress of the display device 10. For example, the first heat dissipation member 351 may be disposed in the first non-folding area NFA1, and the second heat dissipation member 352 may be disposed in the second non-folding area NFA2. A gap between the first heat dissipation member 351 and the second heat dissipation member 352 may overlap the folding area FDA in the thickness direction (Z-axis direction), and may be smaller than the width of the folding area FDA.

The first heat dissipation member 351 and the second heat dissipation member 352 may each be a metal film made of a metal such as copper, nickel, ferrite, or silver having excellent thermal conductivity. For this reason, heat generated in the display device 10 may be emitted to the outside by the first heat dissipation member 351 and the second heat dissipation member 352.

As illustrated in FIG. 6, the light blocking member 320 may be disposed on the digitizer layer 330 and the shielding member 340, and it may thus be possible to prevent steps of the electrode patterns of the digitizer layer 330 or the magnetic metal powders of the shielding member 340 from being viewed by the user on the front surface of the display device 10.

FIG. 7 is an enlarged schematic cross-sectional view of area A of FIG. 6, and schematically illustrates the display panel 100 and the polarizing film 210.

Referring to FIG. 7, the display panel 100 may include a display unit DU including a substrate SUB1 and a thin film transistor layer TFTL, a light emitting element layer EML, and an encapsulation layer TFEL that are disposed on the substrate SUB1, and a touch sensing unit TDU including a touch sensor layer TSL and a total reflection layer TRL.

The substrate SUB1 may be made of an insulating material such as glass, quartz, or a polymer resin. For example, the substrate SUB1 may include polymer resin such as polyethersulfone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT), cellulose acetate propionate (CAP), or a combination thereof. In another embodiment, the substrate SUB1 may include a metal.

The substrate SUB1 may be a flexible substrate that may be bent, folded, and rolled. The substrate SUB1 may be made of polyimide (PI), but is not limited thereto.

The thin film transistor layer TFTL may be disposed on the substrate SUB1. Scan lines, data lines, power lines, scan control lines, routing lines connecting pads and the data lines to each other, and the like, as well as thin film transistors of each of the pixels may be formed in the thin film transistor layer TFTL. Each of the thin film transistors may include a gate electrode, a semiconductor layer, a source electrode, and a drain electrode.

The thin film transistor layer TFTL may be disposed in the display area DA and the non-display area NDA. For example, the thin film transistors of each of the pixels, the scan lines, the data lines, and the power lines of the thin film transistor layer TFTL may be disposed in the display area DA. For example, the scan control lines and link lines of the thin film transistor layer TFTL may be disposed in the non-display area NDA.

The light emitting element layer EML may be disposed on the thin film transistor layer TFTL. The light emitting element layer EML may include pixels each including a first electrode, a light emitting layer, and a second electrode, and a pixel defining layer defining the pixels. The light emitting layer may be an organic light emitting layer including an organic material, and the light emitting layer may include a hole transporting layer, an organic light emitting layer, and an electron transporting layer. In case that a voltage is applied to the first electrode through the thin film transistor of the thin film transistor layer TFTL and a cathode voltage is applied to the second electrode, holes and electrons may move to the organic light emitting layer through the hole transporting layer and the electron transporting layer, respectively, and may be combined with each other in the organic light emitting layer to emit light. The pixels of the light emitting element layer EML may be disposed in the display area DA.

The encapsulation layer TFEL may be disposed on the light emitting element layer EML. The encapsulation layer TFEL may serve to prevent oxygen or moisture from permeating into the light emitting element layer EML. The encapsulation layer TFEL may serve to protect the light emitting element layer EML from foreign substances such as dust.

The encapsulation layer TFEL may be disposed in both the display area DA and the non-display area NDA. For example, the encapsulation layer TFEL may cover the light emitting element layer EML of the display area DA and the non-display area NDA and cover the thin film transistor layer TFTL of the non-display area NDA.

The touch sensor layer TSL may be disposed on the encapsulation layer TFEL. Since the touch sensor layer TSL may be disposed directly on the encapsulation layer TFEL, a thickness of the display device 10 may be reduced as compared with a case where a separate touch panel including the touch sensor layer TSL is attached onto the encapsulation layer TFEL.

The touch sensor layer TSL may include touch electrodes for sensing a user's touch in a capacitance manner and touch lines connecting the pads and the touch electrodes to each other. For example, the touch sensor layer TSL may sense the user's touch in a self-capacitance manner or a mutual capacitance manner.

The touch electrodes of the touch sensor layer TSL may be disposed in the display area DA. The touch lines of the touch sensor layer TSL may be disposed in a touch peripheral area overlapping the non-display area NDA in a thickness direction of the touch sensor layer TSL.

The total reflection layer TRL may be disposed on the touch sensor layer TSL. The total reflection layer TRL may be a layer totally reflecting light traveling in a side direction of the display panel 100 rather than in an upward direction (Z-axis direction) of the display panel 100 among light of the light emitting element layer EML so that the light traveling in the side direction of the display panel 100 may travel in the upward direction of the display panel 100 and adhering the polarizing film 210 disposed on the total reflection layer TRL and the display panel 100 to each other.

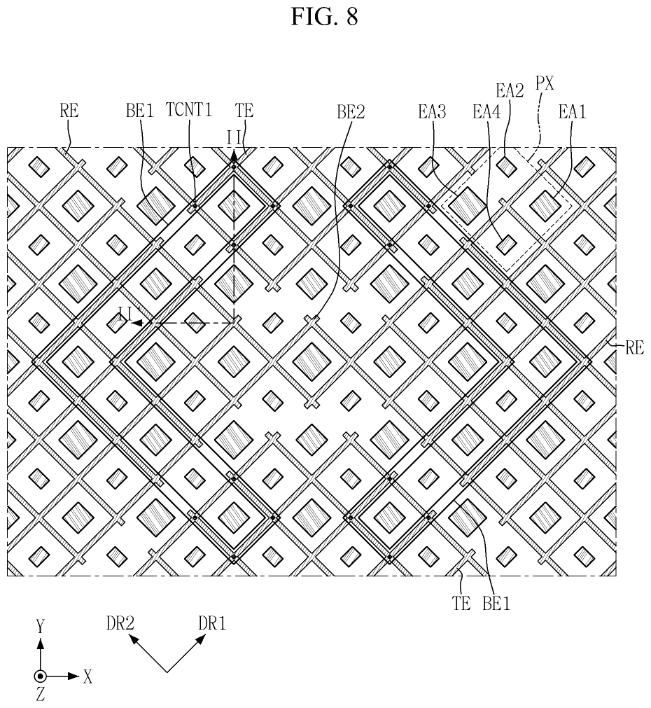

FIG. 8 is a plan view illustrating a touch sensor layer TSL of the display device according to an embodiment. In FIG. 8, for convenience of explanation, light emitting portions EA1, EA2, EA3, and EA4 of the pixels PX, driving electrodes TE, connection portions BE1 and BE2, sensing electrodes RE, and touch contact holes TCNT1 of the touch sensor layer TSL have been illustrated.

The touch sensor layer TSL may include two types of electrodes such as the driving electrodes TE and the sensing electrodes RE. The touch sensor layer TSL may be driven in a mutual capacitive manner of sensing a charge change amount in mutual capacitance of each of multiple touch nodes through the sensing electrodes RE after touch driving signals are applied to the driving electrodes TE.

Multiple driving electrodes TE may be disposed to be spaced apart from each other in the second direction (Y-axis direction), and multiple sensing electrodes RE may be disposed to be spaced apart from each other in the second direction (Y-axis direction). The driving electrodes TE and the sensing electrodes RE may be disposed at a same layer and spaced apart from each other. For example, a gap may be formed between the driving electrode TE and the sensing electrode RE adjacent to each other.

The driving electrodes TE neighboring to each other in the second direction (Y-axis direction) may be connected to each other through first connection portions BE1, as illustrated in FIG. 8. The sensing electrodes RE neighboring to each other in the second direction (Y-axis direction) may be connected to each other through second connection portions BE2, as illustrated in FIG. 8.

Multiple first connection portions BE1 may be formed, and the first connection portions BE1, the driving electrodes TE, and the sensing electrodes RE may be disposed at different layers. The first connection portions BE1 may be bent at least once. It has been illustrated in FIG. 8 that the first connection portions BE1 have a clamp (“<” or “>”) shape in a plan view, but the shape of the first connection portions BE1 in a plan view is not limited thereto. Since the driving electrodes TE adjacent to each other in the second direction (Y-axis direction) are connected to each other by the first connection portions BE1, even though one of the first connection portions BE1 is disconnected, the connection between the driving electrodes TE adjacent to each other in the second direction (Y-axis direction) may be maintained. It has been illustrated in FIG. 8 that the driving electrodes TE adjacent to each other are connected to each other by two first connection portions BE1, but the number of first connection portions BE1 is not limited thereto.

Each of the first connection portions BE1 may overlap the driving electrodes TE adjacent to each other to the second direction (Y-axis direction) in the third direction (Z-axis direction), which is a thickness direction of the substrate SUB1. Each of the first connection portions BE1 may overlap the sensing electrode RE in the third direction (Z-axis direction). A side of the first connection portion BE1 may be connected to one of the driving electrodes TE adjacent to each other in the second direction (Y-axis direction) through the touch contact holes TCNT1. Another side of the first connection portion BE1 may be connected to another one of the driving electrodes TE adjacent to each other in the second direction (Y-axis direction) through the touch contact holes TCNT1.

Due to the first connection portions BE1, the driving electrodes TE and the sensing electrodes RE may be electrically disconnected from each other at each of intersection portions between the driving electrodes TE and the sensing electrodes RE. For this reason, mutual capacitance may be formed at each of the intersection portions between the driving electrodes TE and the sensing electrodes RE.

Each of the driving electrodes TE, the sensing electrodes RE, and the first connection portions BE may have a mesh shape or a net shape in a plan view. For this reason, each of the driving electrodes TE, the sensing electrodes RE, and the first connection portions BE1 may not overlap multiple light emitting portions EA1, EA2, EA3, and EA4 of each of the pixels PX. Therefore, it may prevent a phenomenon in which light emitted from the light emitting portions EA1, EA2, EA3, and EA4 is blocked by the driving electrodes TE, the sensing electrodes RE, and the first connection portions BE1, and luminance of light may not be reduced.

Each of the pixels PX may include a first light emitting portion EA1 emitting light of a first color, a second light emitting portion EA2 emitting light of a second color, a third light emission portion EA3 emitting light of a third color, and a fourth light emitting portion EA4 emitting the light of the second color. For example, the first color may be red, the second color may be green, and the third color may be blue.

The first light emitting portion EA1 and the second light emitting portion EA2 of each of the pixels PX may neighbor to each other in a fourth direction DR2, and the third light emitting portion EA3 and the fourth light emitting portion EA4 of each of the pixels PX may neighbor to each other in the fourth direction DR2. The first light emitting portion EA1 and the fourth light emitting portion EA4 of each of the pixels PX may neighbor to each other in a fifth direction DR1, and the second light emitting portion EA2 and the third light emitting portion EA3 of each of the pixels PX may neighbor to each other in the fifth direction DR1.

Each of the first light emitting portion EA1, the second light emitting portion EA2, the third light emitting portion EA3, and the fourth light emitting portion EA4 may have a rhombic shape or a rectangular shape in a plan view, but is limited thereto. In another embodiment, each of the first light emitting portion EA1, the second light emitting portion EA2, the third light emitting portion EA3, and the fourth light emitting portion EA4 may have a polygonal shape other than a quadrangular shape, a circular shape, or an elliptical shape in a plan view. It has been illustrated in FIG. 8 that the third light emitting portion EA3 has the greatest area and the second light emitting portion EA2 and the fourth light emitting portion EA4 have the smallest area, but the disclosure is not limited thereto.

The second light emitting portions EA2 and the fourth light emitting portions EA4 may be disposed in odd-numbered rows. The second light emitting portions EA2 and the fourth light emitting portions EA4 may be disposed side by side in the first direction (X-axis direction) in each of the odd-numbered rows. The second light emitting portions EA2 and the fourth light emitting portions EA4 may be alternately disposed in each of the odd-numbered rows. Each of the second light emitting portions EA2 may have long sides in the fourth direction DR2 and short sides in the fifth direction DR1, while each of the fourth light emitting portions EA4 may have short sides in the fourth direction DR2 and long sides in the fifth direction DR1. The fourth direction DR2 may be a direction between the first direction (X-axis direction) and the second direction (Y-axis direction), and may be a direction inclined by 45° with respect to the first direction (X-axis direction). The fifth direction DR1 may be a direction perpendicular to the fourth direction DR2.

The first light emitting portions EA1 and the third light emitting portions EA3 may be disposed in even-numbered rows. The first light emitting portions EA1 and the third light emitting portions EA3 may be disposed side by side in the first direction (X-axis direction) in each of the even-numbered rows. The first light emitting portions EA1 and the third light emitting portions EA3 may be alternately disposed in each of the even-numbered rows.

The second light emitting portions EA2 and the fourth light emitting portions EA4 may be disposed in odd-numbered columns. The second light emitting portions EA2 and the fourth light emitting portions EA4 may be disposed side by side in the second direction (Y-axis direction) in each of the odd-numbered columns. The second light emitting portions EA2 and the fourth light emitting portions EA4 may be alternately disposed in each of the odd-numbered columns.

The first light emitting portions EA1 and the third light emitting portions EA3 may be disposed in even-numbered columns. The first light emitting portions EA1 and the third light emitting portions EA3 may be disposed side by side in the second direction (Y-axis direction) in each of the even-numbered columns. The first light emitting portions EA1 and the third light emitting portions EA3 may be alternately disposed in each of the even-numbered columns.

FIG. 9 is a schematic cross-sectional view of the display device 10 according to an embodiment taken along line II-II′ of FIG. 8.

Referring to FIG. 9, a barrier film BR may be disposed on the substrate SUB1. The substrate SUB1 may be made of an insulating material such as a polymer resin. For example, the substrate SUB1 may be made of polyimide. The substrate SUB1 may be a flexible substrate that may be bent, folded, and rolled.

The barrier film BR may be a film for protecting transistors of the thin film transistor layer TFTL and light emitting layers 172 of the light emitting element layer EML from moisture permeating through the substrate SUB1 vulnerable to moisture permeation. The barrier film BR may include multiple inorganic films that are alternately stacked each other. For example, the barrier film BR may be formed as multiple films in which one or more inorganic films of a silicon nitride layer, a silicon oxynitride layer, a silicon oxide layer, a titanium oxide layer, and an aluminum oxide layer are alternately stacked each other.

Thin film transistors ST1 may be disposed on the barrier film BR. Each of the thin film transistors ST1 may include an active layer ACT1, a gate electrode G1, a source electrode S1, and a drain electrode DI.

The active layer ACT1, the source electrode S1, and the drain electrode DI of the thin film transistor ST1 may be disposed on the barrier film BR. The active layer ACT1 of the thin film transistor ST1 may include polycrystalline silicon, single crystal silicon, low-temperature polycrystalline silicon, amorphous silicon, or an oxide semiconductor. The active layer ACT1 overlapping the gate electrode G1 in the third direction (Z-axis direction), which is the thickness direction of the substrate SUB1, may be defined as a channel region. The source electrode S1 and the drain electrode DI may be regions that do not overlap the gate electrode G1 in the third direction (Z-axis direction), and may have conductivity by doping a silicon semiconductor or an oxide semiconductor with ions or impurities.

A gate insulating film 130 may be disposed on the active layer ACT1, the source electrode S1, and the drain electrode DI of each of the thin film transistors ST1. The gate insulating film 130 may be formed as an inorganic film including a silicon nitride layer, a silicon oxynitride layer, a silicon oxide layer, a titanium oxide layer, or an aluminum oxide layer.

The gate electrode G1 of the thin film transistor ST1 may be disposed on the gate insulating film 130. The gate electrode G1 may overlap the active layer ACT1 in the third direction (Z-axis direction). The gate electrode G1 may be formed as a single layer or multiple layers made of one of molybdenum (Mo), aluminum (Al), chromium (Cr), gold (Au), titanium (Ti), nickel (Ni), neodymium (Nd), and copper (Cu), or an alloy thereof.

An interlayer insulating film may include a first interlayer insulating film 141 and a second interlayer insulating film 142. The first interlayer insulating film 141 may be disposed on the gate electrode G1 of the thin film transistor ST1. The first interlayer insulating film 141 may be formed as an inorganic film including a silicon nitride layer, a silicon oxynitride layer, a silicon oxide layer, a titanium oxide layer, or an aluminum oxide layer. The first interlayer insulating film 141 may be formed as multiple inorganic films.

Capacitor electrodes CAE may be disposed on the first interlayer insulating film 141. The capacitor electrode CAE may overlap the gate electrode G1 of the thin film transistor ST1 in the third direction (Z-axis direction). Since the first interlayer insulating film 141 has a dielectric constant, a capacitor may be formed by the capacitor electrode CAE, the gate electrode G1, and the first interlayer insulating film 141 disposed between the capacitor electrode CAE and the gate electrode G1. The capacitor electrode CAE may be formed as a single layer or multiple layers made of one of molybdenum (Mo), aluminum (Al), chromium (Cr), gold (Au), titanium (Ti), nickel (Ni), neodymium (Nd), and copper (Cu), or an alloy thereof.

The second interlayer insulating film 142 may be disposed on the capacitor electrodes CAE. The second interlayer insulating film 142 may be formed as an inorganic film including a silicon nitride layer, a silicon oxynitride layer, a silicon oxide layer, a titanium oxide layer, or an aluminum oxide layer. The second interlayer insulating film 142 may be formed as multiple inorganic films.

First anode connection electrodes ANDE1 may be disposed on the second interlayer insulating film 142. The first anode connection electrode ANDE1 may be connected to the drain electrode DI of the thin film transistor ST1 through a first connection contact hole ANCT1 penetrating through the gate insulating film 130, the first interlayer insulating film 141, and the second interlayer insulating film 142. The first anode connection electrode ANDE1 may be formed as a single layer or multiple layers made of one of molybdenum (Mo), aluminum (Al), chromium (Cr), gold (Au), titanium (Ti), nickel (Ni), neodymium (Nd), and copper (Cu), or an alloy thereof.

A first planarization film 160 for planarizing a step due to the thin film transistors ST1 may be disposed on the first anode connection electrodes ANDE1. The first planarization film 160 may be formed as an organic film made of an acrylic resin, an epoxy resin, a phenolic resin, a polyamide resin, a polyimide resin, or the like.

Second anode connection electrodes ANDE2 may be disposed on the first planarization film 160. The second anode connection electrode ANDE2 may be connected to the first anode connection electrode ANDE1 through a second connection contact hole ANCT2 penetrating through the first planarization film 160. The second anode connection electrode ANDE2 may be formed as a single layer or multiple layers made of one of molybdenum (Mo), aluminum (Al), chromium (Cr), gold (Au), titanium (Ti), nickel (Ni), neodymium (Nd), and copper (Cu), or an alloy thereof.

A second planarization film 180 may be disposed on the second anode connection electrodes ANDE2. The second planarization film 180 may be formed as an organic film made of an acrylic resin, an epoxy resin, a phenolic resin, a polyamide resin, a polyimide resin, or the like.

Light emitting elements LEL and a bank 190 may be disposed on the second planarization film 180. Each of the light emitting elements LEL may include a pixel electrode 171, a light emitting layer 172, and a common electrode 173.

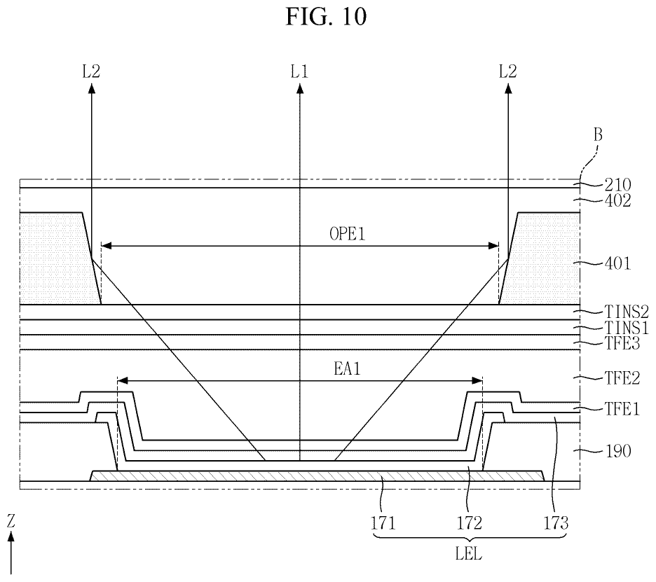

FIG. 10 is an enlarged schematic cross-sectional view of area B of FIG. 9, and schematically illustrates the first light emitting portion EA1, the encapsulation layer TFEL, the touch sensor layer TSL, and the total reflection layer TRL adjacent to the first light emitting portion EA1. The first light emitting portion EA1 will be representatively described, and the second to fourth light emitting portions EA2, EA3, and EA4 will also be described.

Referring to FIGS. 9 and 10, the pixel electrode 171 may be disposed on the second planarization film 180. The pixel electrode 171 may be connected to the second anode connection electrode ANDE2 through a third connection contact hole ANCT3 penetrating through the second planarization film 180.

In a top emission structure in which light is emitted toward the common electrode 173 from the light emitting layer 172, the pixel electrode 171 may be made of a metal having high reflectivity, such as a stacked structure (Ti/Al/Ti) of aluminum and titanium, a stacked structure (ITO/AI/ITO) of aluminum and indium tin oxide (ITO), an APC alloy, and a stacked structure (ITO/APC/ITO) of an APC alloy and ITO. The APC alloy may be an alloy of silver (Ag), palladium (Pd), and copper (Cu).

The bank 190 may be formed to partition the pixel electrodes 171 on the second planarization film 180, in order to define the first light emitting portion EA1, the second light emitting portion EA2, the third light emitting portion EA3, and the fourth light emitting portion EA4. The bank 190 may cover edges of the pixel electrode 171. The bank 190 may be formed as an organic film made of an acrylic resin, an epoxy resin, a phenolic resin, a polyamide resin, a polyimide resin, or the like.

Each of the first light emitting portion EA1, the second light emitting portion EA2, the third light emitting portion EA3, and the fourth light emitting portion EA4 may be an area where the pixel electrode 171, the light emitting layer 172, and the common electrode 173 are sequentially stacked and holes from the pixel electrode 171 and electrons from the common electrode 173 are combined with each other in the light emitting layer 172 to emit light.

The light emitting layer 172 may be disposed on the pixel electrode 171 and the bank 190. The light emitting layer 172 may include an organic material to emit light of a color. For example, the light emitting layer 172 may include a hole transporting layer, an organic material layer, and an electron transporting layer.

The common electrode 173 may be disposed on the light emitting layer 172. The common electrode 173 may cover the light emitting layer 172. The common electrode 173 may be a common layer commonly formed in the first light emitting portion EA1, the second light emitting portion EA2, the third light emitting portion EA3, and the fourth light emitting portion EA4. A capping layer (not illustrated) may be formed on the common electrode 173.

In the top emission structure, the common electrode 173 may be made of a transparent conductive material (TCO) such as ITO or indium zinc oxide (IZO) capable of transmitting light through the common electrode 173 or a semi-transmissive conductive material such as magnesium (Mg), silver (Ag), or an alloy of magnesium (Mg) and silver (Ag). In case that the common electrode 173 is made of a semi-transmissive conductive material, emission efficiency may be increased by a micro cavity.

The encapsulation layer TFEL may be disposed on the common electrode 173. The encapsulation layer TFEL may include at least one inorganic film in order to prevent oxygen or moisture from permeating into the light emitting element layer EML. The encapsulation layer TFEL may include at least one organic film in order to protect the light emitting element layer EML from foreign substances such as dust. For example, the encapsulation layer TFEL may include a first encapsulation inorganic film TFE1, an encapsulation organic film TFE2, and a second encapsulation inorganic film TFE3.

The first encapsulation inorganic film TFE1 may be disposed on the common electrode 173, the encapsulation organic film TFE2 may be disposed on the first encapsulation inorganic film TFE1, and the second encapsulation inorganic film TFE3 may be disposed on the encapsulation organic film TFE2. Each of the first encapsulation inorganic film TFEL and the second encapsulation inorganic film TFE3 may be formed as multiple films in which one or more inorganic films of a silicon nitride layer, a silicon oxynitride layer, a silicon oxide layer, a titanium oxide layer, and an aluminum oxide layer are alternately stacked each other. The encapsulation organic film TFE2 may be an organic film made of an acrylic resin, an epoxy resin, a phenolic resin, a polyamide resin, a polyimide resin, or the like.

The touch sensor layer TSL may be disposed on the encapsulation layer TFEL. The touch sensor layer TSL may include a first touch insulating film TINS1, the first connection portions BE1, a second touch insulating film TINS2, the driving electrodes TE, and the sensing electrodes RE.

The first touch insulating film TINS1 may be formed as an inorganic film including a silicon nitride layer, a silicon oxynitride layer, a silicon oxide layer, a titanium oxide layer, or an aluminum oxide layer.

The first connection portions BE1 may be disposed on the first touch insulating film TINS1. The first connection portion BE1 may be formed as a single layer or multiple layers made of one of molybdenum (Mo), aluminum (Al), chromium (Cr), gold (Au), titanium (Ti), nickel (Ni), neodymium (Nd), and copper (Cu), or an alloy thereof.

The second touch insulating film TINS2 may be disposed on the first connection portions BE1. The second touch insulating film TINS2 may be formed as an inorganic film including a silicon nitride layer, a silicon oxynitride layer, a silicon oxide layer, a titanium oxide layer, or an aluminum oxide layer. In another embodiment, the second touch insulating film TINS2 may be formed as an organic film made of an acrylic resin, an epoxy resin, a phenolic resin, a polyamide resin, a polyimide resin, or the like.

The driving electrodes TE and the sensing electrodes RE may each be disposed on the second touch insulating film TINS2. Dummy patterns, first touch driving lines, second touch driving lines, and touch sensing lines as well as the driving electrodes TE and the sensing electrodes RE may be disposed on the second touch insulating film TINS2. Each of the driving electrodes TE and the sensing electrodes RE may be formed as a single layer or multiple layers made of one of molybdenum (Mo), aluminum (Al), chromium (Cr), gold (Au), titanium (Ti), nickel (Ni), neodymium (Nd), and copper (Cu), or an alloy thereof.

The driving electrode TE and the sensing electrode RE may overlap the first connection portions BE1 in the third direction (Z-axis direction). The driving electrode TE may be connected to the first connection portion BE1 through the touch contact hole TCNT1 penetrating through the first touch insulating film TINS1.

The total reflection layer TRL may be disposed on the touch sensor layer TSL. The total reflection layer TRL may be a layer totally reflecting light traveling in the side direction rather than in the upward direction (Z-axis direction) among the light from the light emitting element portions EA1, EA2, EA3, and EA4 so that the light traveling in the side direction travels in the upward direction (Z-axis direction). The total reflection layer TRL may include a low refractive pattern 401 and a high refractive adhesive layer 402.

The low refractive pattern 401 may be disposed on the second touch insulating film TINS2. The low refractive pattern 401 may overlap the bank 190, and may not overlap the light emitting portions EA1, EA2, EA3, and EA4 in the third direction (Z-axis direction). The low refractive pattern 401 may overlap the driving electrode TE, the connection portions BE1 and BE2, and/or the sensing electrode RE in the third direction (Z-axis direction).

The low refractive pattern 401 may have a cross section with a tapered or trapezoidal shape. The low refractive pattern 401 may include an inclined surface adjacent to each of the light emitting portions EA1, EA2, EA3, and EA4. A tapered angle of the inclined surface of the low refractive pattern 401 may be less than or equal to about 90°. The tapered angle of the low refractive pattern 401 may be an inclination angle of the inclined surface formed between the second touch insulating film TINS2 and the inclined surface of the low refractive pattern 401.

Referring to FIGS. 9 and 10, the low refractive pattern 401 may include multiple openings OPE1, and each of the openings OPE1 may overlap each of the light emitting portions EA1, EA2, EA3, and EA4 in the third direction (Z-axis direction). Each of the openings OPE1 of the low refractive pattern 401 may have an area greater than each of the corresponding light emitting portions EA1, EA2, EA3, and EA4.

The low refractive pattern 401 may be formed as an organic film or formed as an organic film including an inorganic filler. The organic film may be made of an acryl resin, a methacrylic resin, polyisoprene, a vinyl resin, an epoxy resin, a phenolic resin, a urethane resin, a polyamide resin, or a polyimide resin, but is not limited thereto. The inorganic filler may be a metal particle, but is not limited thereto.

In an embodiment, a refractive index of the low refractive pattern 401 may be in a range of about 1.40 to about 1.60. In an embodiment, a refractive index of the low refractive pattern 401 may be in a range of about 1.45 to about 1.55. The refractive index described herein may be measured using an optical measuring instrument such as an ellipsometer or a spectral reflectometer. The ellipsometer may measure a refractive index of an inorganic film by measuring a polarization change amount of incident light and reflected light on the inorganic film and calculating a thickness and a complex refractive index of the inorganic film. The spectral reflectophotometer may measure a refractive index of an inorganic film by comparing intensities of light obtained by changing a wavelength with each other. The refractive index may be a value measured at normal temperature and pressure.

The high refractive adhesive layer 402 may be disposed on the low refractive pattern 401 and the second touch insulating film TINS2. The high refractive adhesive layer 402 may fill the openings of the low refractive pattern 401 and cover the low refractive pattern 401. Accordingly, the high refractive adhesive layer 402 may serve to planarize a step formed by the driving electrodes TE, the sensing electrodes RE, and the first connection portions BE1. The high refractive adhesive layer 402 may adhere or bond the display panel 100 and the front stacked structure 200 to each other. The high refractive adhesive layer 402 may be in contact with the second touch insulating film TINS2 on a lower surface oof the high refractive adhesive layer 402 and in contact with the polarizing film 210 on an upper surface of the high refractive adhesive layer 402.

In an embodiment, a refractive index of the high refractive adhesive layer 402 may be in a range of about 1.55 to about 1.65. In an embodiment, a refractive index of the high refractive adhesive layer 402 may be in a range of about 1.58 to about 1.62. In an embodiment, the refractive index of the high refractive adhesive layer 402 may be greater than the refractive index of the low refractive pattern 401.

Referring to FIG. 10, light emitted from the light emitting element LEL may include front light L1 emitted in a front direction (Z-axis direction) and side light L2 emitted in a side direction other than the front direction. The side light L2 may be refracted or totally reflected at an interface between the low refractive pattern 401 and the high refractive adhesive layer 402 depending on a difference in refractive index between the low refractive pattern 401 and the high refractive adhesive layer 402. In case that an optical path of the side light L2 is changed to the front direction (Z-axis direction), light efficiency may be increased.

The high refractive adhesive layer 402 may include an aromatic monomer, an aliphatic monomer, a xylene resin, a plasticizer, and inorganic particles. The high refractive adhesive layer 402 may be formed by curing a composition including two or more aromatic monomers, three or more aliphatic monomers, one or more xylene resins, one or more plasticizers, and inorganic particles.

The high refractive adhesive layer 402 may include an aromatic monomer, which may increase the refractive index. The aromatic monomer may be an aromatic (meth)acrylate. The aromatic (meth)acrylate may be a (meth)acrylate monomer including at least one aromatic substituent. A type of the aromatic (meth)acrylate is not particularly limited, but examples of the aromatic (meth)acrylate may include (meth)acrylate including an aryl group in which the number of carbon atoms forming a ring is 6 to 30, 6 to 20, or 6 to 10, and the like.

As the aromatic (meth)acrylate, a monofunctional or polyfunctional aromatic (meth)acrylate monomer may be used.

Examples of the monofunctional aromatic (meth)acrylate monomer may include phenyl (meth)acrylate, benzyl (meth)acrylate, phenoxyethyl (meth)acrylate, phenoxypropyl (meth)acrylate, phenoxydiethylene glycol (meth)acrylate, phenoxyhydroxypropyl (meth)acrylate, phenylthioethyl (meth)acrylate, phenylbenzyl (meth)acrylate, and the like, but are not limited thereto.

Examples of the polyfunctional aromatic (meth)acrylate monomer may include a bifunctional aromatic (meth)acrylate monomer and the like. For example, examples of the polyfunctional aromatic (meth)acrylate monomer may include bisphenol A (meth)acrylate, bisphenol A ethoxy (meth)acrylate, 2,2-bis((meth)acryloxyphenyl)propane, 2,2-bis[4-(3-(meth)acryloxy)-2-hydroxypropoxyphenyl]propane, 2,2-bis(4-(meth)acryloxyethoxyphenyl)propane, 2,2-bis(4-(meth)acryloxydiethoxyphenyl) propane, 2,2-bis(4-(meth)acryloxytriethoxyphenyl)propane, 2,2-bis(4-(meth)acryloxytetraethoxyphenyl)propane, 2,2-bis(4-(meth)acryloxypentaethoxyphenyl)propane, 2,2-bis(4-(meth)acryloxypropoxyphenyl)propane, 2(4-(meth)acryloxydiethoxyphenyl)-2(4-(meth)acryloxydiethoxyphenyl)propane, 2(4-(meth)acryloxydiethoxyphenyl)-2(4-(meth)acryloxytricthoxyphenyl)propane, 2,2-bis(4-(meth)acryloxypropoxyphenyl)propane, 2,2-bis(4-(meth)acryloxyisopropoxyphenyl)propane, 2(4-acryloxydipropoxyphenyl)-2(4-(meth)acryloxytriethoxyphenyl)propane, and the like, but are not limited thereto.

The high refractive adhesive layer 402 may include a first aromatic monomer and a second aromatic monomer. The first aromatic monomer and the second aromatic monomer may be different from each other, and may each be a monofunctional aromatic (meth)acrylate. In an embodiment, the first aromatic monomer may be an aromatic (meth)acrylate that includes sulfur, and the second aromatic monomer may be an aromatic (meth)acrylate that does not include sulfur. In an embodiment, a molecular weight of the first aromatic monomer may be less than a molecular weight of the second aromatic monomer. In an embodiment, the molecular weight of the first aromatic monomer may be less than about 220 g/mol, and the molecular weight of the second aromatic monomer may be greater than or equal to about 220 g/mol. In an embodiment, the molecular weight of the first aromatic monomer may be in a range of about 100 g/mol to about 210 g/mol, and the molecular weight of the second aromatic monomer may be in a range of about 220 g/mol to about 400 g/mol. In an embodiment, the first aromatic monomer may be 2-(phenyl) thioethyl acrylate, and the second aromatic monomer may be o-phenylbenzyl acrylate.

The high refractive adhesive layer 402 may include an aliphatic monomer, which may increase flexibility and decrease rigidity. The aliphatic monomer may be an aliphatic (meth)acrylate, which may be a monofunctional or polyfunctional aliphatic (meth)acrylate.

Examples of the monofunctional aliphatic (meth)acrylate may include methyl (meth)acrylate, ethyl (meth)acrylate, propyl (meth)acrylate, n-butyl (meth)acrylate, iso-butyl (meth)acrylate, t-butyl (meth)acrylate, hexyl (meth)acrylate, 2-ethylhexyl (meth)acrylate, iso-octyl (meth)acrylate, iso-nonyl (meth)acrylate, iso-pentyl (meth)acrylate, tridecyl (meth)acrylate, stearyl (meth)acrylate, lauryl (meth)acrylate, hydroxybutyl (meth)acrylate, 2-{2-[(2-ethylhexyl)oxylethoxy} ethyl acrylate (DEHEA), and the like, but are not limited thereto.

Examples of the polyfunctional aliphatic (meth)acrylate may include: a bifunctional aliphatic (meth)acrylate such as ethylene glycol di(meth)acrylate, diethylene glycol di (meth)acrylate, triethylene glycol di(meth)acrylate, butylene glycol di(meth)acrylate, neopentyl glycol di(meth)acrylate, propylene glycol di(meth)acrylate, 1,3-butanediol di (meth)acrylate, 1,4-butanediol di(meth)acrylate, and 1,6-hexanediol di(meth)acrylate; a trifunctional aliphatic (meth)acrylate such as trimethylolpropane tri (meth)acrylate, trimethylolethane tri (meth)acrylate, trimethylolethanol tri (meth)acrylate, and trimethylolmethane tri (meth)acrylate; and a tetrafunctional aliphatic (meth)acrylate such as pentaerythritol tetra(meth)acrylate, but are not limited thereto.

The high refractive adhesive layer 402 may include a first aliphatic monomer, a second aliphatic monomer, and a third aliphatic monomer. The first to third aliphatic monomers may be different from each other, and may each be a monofunctional aliphatic (meth)acrylate. The first aliphatic monomer and the second aliphatic monomer may be aliphatic (meth)acrylates including a branched chain alkyl group, and the third aliphatic monomer may be an aliphatic (meth)acrylate including a straight chain alkyl group and a hydroxy group. In an embodiment, a molecular weight of the first aliphatic monomer may be greater than a molecular weight of the second aliphatic monomer and a molecular weight of the third aliphatic monomer, and the molecular weight of the second aliphatic monomer may be greater than the molecular weight of the third aliphatic monomer. In an embodiment, the molecular weight of the first aliphatic monomer may be greater than or equal to about 250 g/mol, the molecular weight of the second aliphatic monomer may be in a range of about 150 g/mol to about 200 g/mol, and the molecular weight of the third aliphatic monomer may be less than about 150 g/mol. In an embodiment, the first aliphatic monomer may be 2-{2-[(2-ethylhexyl)oxylethoxy} ethyl acrylate (DEHEA), the second aliphatic monomer may be 2-ethylhexyl acrylate, and the third aliphatic monomer may be 4-hydroxybutyl acrylate.

The high refractive adhesive layer 402 may include a xylene resin, which may increase the refractive index of the high refractive adhesive layer 402 and increase the flexibility of the high refractive adhesive layer 402. Examples of the xylene resin may include a straight-type xylene resin, an alkylphenol-modified xylene resin, a phenol-modified novolak-type xylene resin, a phenol-modified resol-type xylene resin, a polyol-modified xylene resin, hydrogenated rosine ester, and the like, but are not limited thereto. Another type of xylene resin may be used as the xylene resin. In an embodiment, the xylene resin may be represented by the following Formula 1:

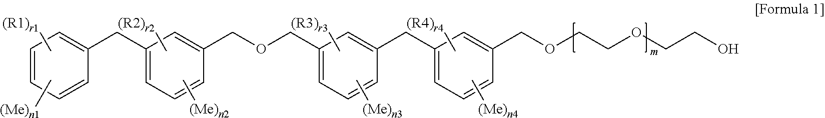

In Formula 1, Me may be a methyl group, R1 to R4 may each independently be hydrogen, deuterium, halogen, a substituted or unsubstituted alkyl group, a substituted or unsubstituted aryl group, or a substituted or unsubstituted heteroaryl group, n1 to n4 may each independently be an integer of 0 to 4 and at least one of n1 to n4 may be 2 or more, r1 to r4 may each independently be an integer of 0 to 4, and m may be an integer of 0 to 20.

In an embodiment, n1+r1 may be 4, n2+r2 may be 4, n3+r3 may be 4, and n4+r4 may be 4.

In an embodiment, n1 to n4 may all be 2.

In an embodiment, Formula 1 may be the following Formula 1-1, and m may be an integer of 0 to 100.

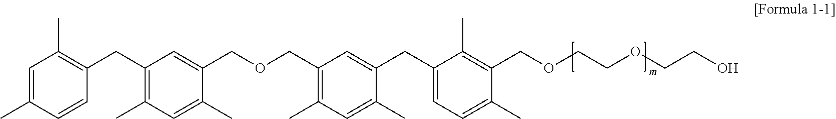

The high refractive adhesive layer 402 may include a plasticizer, which may decrease the rigidity of the high refractive adhesive layer 402 and increase the flexibility of the high refractive adhesive layer 402. A sulfide aromatic compound may be used as the plasticizer. The sulfide aromatic compound may be diphenyl sulfide, methyl phenyl sulfide, 4-methoxythioanisole, 2-(phenylthio) ethanol, methoxymethyl phenyl sulfide, bis(4-hydroxyphenyl) sulfide, bis(4-aminophenyl) sulfide, bis(2-aminophenyl) sulfide, bis(phenylthio) methane, thioxanthen-9-one, 2-chlorothioxanthone, thianthrene, 2-aminophenyl phenyl sulfide, 4,4′-dipyridyl sulfide, 1,2-bis(phenylthio) ethane, phenyl trifluoromethyl sulfide, phenylvinyl sulfide, allyl phenyl sulfide, 2-(methylthio) aniline, 2-(methylthio) pyridine, 2-fluorothioanisole, 2-chlorothioanisole, 2-bromothioanisole, 4-bromothioanisole, 4-(methylthio) benzaldehyde, (phenylthio) acetonitrile, 2-methoxythioanisole, 2-methyl-3-(methylthio) furan, S-phenyl thioacetate, or (oxybis(ethane-2,1-diyl))bis(phenylsulfan).

In an embodiment, the sulfide aromatic compound may be represented by the following Formula 2:

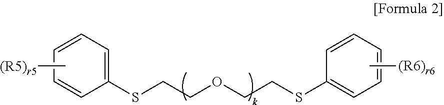

In Formula 2, R5 and R6 may each independently be hydrogen, deuterium, halogen, a substituted or unsubstituted alkyl group, a substituted or unsubstituted aryl group, or a substituted or unsubstituted heteroaryl group, r5 and r6 may each independently be integers of 0 to 5, and k may be an integer of 0 to 3.

In an embodiment, Formula 2 may be represented by one of the following compounds.

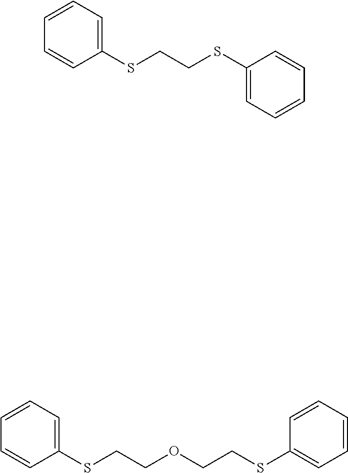 [SMILES: c1ccc(SCCSc2ccccc2)cc1 ; c1ccc(SCCOCCSc2ccccc2)cc1]

The high refractive adhesive layer 402 may include inorganic particles, which may adjust the refractive index of the high refractive adhesive layer 402. The inorganic particles may include at least one of zirconium oxide (ZrO₂), titanium oxide (TiO₂), aluminum oxide (Al₂O₃), and silicon oxide (SiO₂). In an embodiment, the inorganic particles may include zirconium oxide (ZrO₂). The inorganic particles may be dispersed in the high refractive adhesive layer 402 and widely spread over the high refractive adhesive layer 402.

The inorganic particles may be implemented in various shapes. For example, shapes of the inorganic particles may be spherical, plate-shaped, cubic, or amorphous, but are not limited thereto. An average particle diameter of the inorganic particles may be less than or equal to about 25 nm. For example, the average particle diameter of the inorganic particles may be in a range of about 1 nm to about 25 nm. The average particle diameter of the inorganic particles may be a particle size (D₅₀) at 50 vol % in a cumulative size-distribution curve.

In an embodiment, the high refractive adhesive layer 402 may include 40 wt % to 80 wt % of the aromatic monomer based on the total weight of the high refractive adhesive layer 402. The high refractive adhesive layer 402 may include 10 wt % to 30 wt % of the aliphatic monomer based on the total weight of the high refractive adhesive layer 402. The high refractive adhesive layer 402 may include 10 wt % to 25 wt % of the xylene resin based on the total weight of the high refractive adhesive layer 402. The high refractive adhesive layer 402 may include 10 wt % to 20 wt % of the sulfide aromatic compound based on the total weight of the high refractive adhesive layer 402. The high refractive adhesive layer 402 may include 1 wt % to 3 wt % of the inorganic particles based on the total weight of the high refractive adhesive layer 402.

In an embodiment, the high refractive adhesive layer 402 may include 40 wt % to 60 wt % of the aromatic monomer based on the total weight of the high refractive adhesive layer 402. The high refractive adhesive layer 402 may include 15 wt % to 25 wt % of the aliphatic monomer based on the total weight of the high refractive adhesive layer 402. The high refractive adhesive layer 402 may include 15 wt % to 20 wt % of the xylene resin based on the total weight of the high refractive adhesive layer 402. The high refractive adhesive layer 402 may include 10 wt % to 15 wt % of the sulfide aromatic compound based on the total weight of the high refractive adhesive layer 402. The high refractive adhesive layer 402 may include 1 wt % to 2 wt % of the inorganic particles based on the total weight of the high refractive adhesive layer 402.

The high refractive adhesive layer 402 may have high refractive characteristics by including the aromatic monomer, and the flexibility of the high refractive adhesive layer 402 may be increased by introducing the aliphatic monomer into the high refractive adhesive layer 402. In case that a content of the inorganic particles exceeds 3 wt %, the high refractive adhesive layer 402 may have high strength but may be readily broken. By setting the content of the inorganic particles within 3 wt %, it may be possible to increase emission efficiency while preventing the high refractive adhesive layer 402 from being broken. Accordingly, the high refractive adhesive layer 402 may be applied as an adhesive layer of the foldable display device 10. The content may be based on the total weight of the high refractive adhesive layer 402.

In an embodiment, a content of the first aromatic monomer may be higher than a content of the second aromatic monomer. A mass ratio between the first aromatic monomer and the second aromatic monomer may be in a range of about 1.5:1 to about 3:1.

In an embodiment, a content of the first aliphatic monomer may be significantly higher than a content of the second aliphatic monomer and a content of the third aliphatic monomer, and the content of the second aliphatic monomer may be higher than the content of the third aliphatic monomer. A mass ratio between the first aromatic monomer and the third aromatic monomer may be in a range of about 7:1 to about 10:1. A mass ratio between the second aromatic monomer and the third aromatic monomer may be in a range of about 1.5:2 to about 3:1.

The high refractive adhesive layer 402 may further include an additive in an embodiment. A general additive may be appropriately used as the additive in order to adjust physical properties required for a resin composition. Examples of the additive may include a light stabilizer, a cross-linking agent, an antioxidant, a chain transfer agent, a photosensitizer, a polymerization inhibitor, a leveling agent, a surfactant, an ultraviolet absorber, a storage stabilizer, an antistatic agent, an inorganic filler, a pigment, and a dye, but are not limited thereto. The additive may be used alone or used in a combination of two or more additives.

The high refractive adhesive layer 402 may have a storage modulus (G′) in a range of about 1.0 MPa to about 10 MPa at −20° C. The high refractive adhesive layer 402 may have a storage modulus in a range of about 0.01 MPa to about 0.1 MPa at room temperature (25° C.). The high refractive adhesive layer 402 may have a storage modulus in a range of about 0.01 MPa to about 0.05 MPa at 60° C. For example, the storage modulus of the high refractive adhesive layer 402 at −20° C. may be in a range of about 1.5 MPa to about 3.0 MPa, the storage modulus of the high refractive adhesive layer 402 at room temperature (25° C.) may be in a range of about 0.015 MPa to about 0.05 MPa, and the storage modulus of the high refractive adhesive layer 402 at 60° C. may be in a range of about 0.01 MPa to about 0.03 MPa.

The high refractive adhesive layer 402 may have a loss modulus (G″) in a range of about 3.5 MPa to about 10 MPa at −20° C. The high refractive adhesive layer 402 may have a loss modulus in a range of about 0.001 MPa to about 0.1 MPa at room temperature (25° C.). The high refractive adhesive layer 402 may have a loss modulus in a range of about 0.001 MPa to about 0.01 MPa at 60° C. For example, the loss modulus of the high refractive adhesive layer 402 at −20° C. may be in a range of about 4.5 MPa to about 7.0 MPa, the loss modulus of the high refractive adhesive layer 402 at room temperature (25° C.) may be in a range of about 0.005 MPa to about 0.01 MPa, and the loss modulus of the high refractive adhesive layer 402 at 60° C. may be in a range of about 0.001 MPa to about 0.005 MPa.

The storage modulus (G′) may be energy stored without loss by elasticity, and the loss modulus (G″) may be energy lost due to viscosity. A viscoelastic ratio (Tan delta) may be a ratio (G″/G′) of the loss modulus (G″) to the storage modulus (G′), and as the viscoelastic ratio is greater than 1, it means that viscosity may be greater than elasticity. The storage modulus and the loss modulus may be measured by a method well known to one of ordinary skill in the art. In an embodiment, the storage modulus and the loss modulus may be measured by dynamic mechanical analysis (DMA), and the viscoelastic ratio may also be calculated. The storage modulus, the loss modulus, and the viscoelastic ratio may be measured or calculated by ASTM D4065, D4440, and D5279, respectively.

The high refractive adhesive layer 402 may have a viscoelastic ratio in a range of about 2.9 to about 6 at −20° C. The high refractive adhesive layer 402 may have a viscoelastic ratio in a range of about 0.1 to about 1 at room temperature (25° C.). The high refractive adhesive layer 402 may have a viscoelastic ratio in a range of about 0.01 to about 0.5 at 60° C. For example, the viscoelastic ratio of the high refractive adhesive layer 402 at −20° C. may be in a range of about 3.0 to about 4.0, the viscoelastic ratio of the high refractive adhesive layer 402 at room temperature (25° C.) may be in a range of about 0.3 to about 0.6, and the viscoelastic ratio of the high refractive adhesive layer 402 at 60° C. may be in a range of about 0.05 to about 0.2.

In case that the storage modulus, the loss modulus, and the viscoelastic ratio of the high refractive adhesive layer 402 satisfy the above ranges at each temperature, the flexibility of the high refractive adhesive layer 402 may be increased, and durability of the high refractive adhesive layer 402 may be maintained even in case that the display device 10 is folded. The viscoelastic ratio of the high refractive adhesive layer 402 at a low temperature may be high, such that adhesive strength may be excellent, and the storage modulus of the high refractive adhesive layer 402 at a low temperature may be high, such that a crack may be prevented. In case that the storage modulus, the loss modulus, and the viscoelastic ratio of the high refractive adhesive layer 402 are out of the above ranges at each temperature, deformation of the high refractive adhesive layer 402 according to a temperature may increase, such that durability and reliability of the display device 10 may decrease.

A glass transition temperature (Tg) of the high refractive adhesive layer 402 may be in a range of about −30° C. to about −10° C. For example, the glass transition temperature (Tg) of the high refractive adhesive layer 402 may be in a range of about −25° C. to about −15° C. In case that the high refractive adhesive layer 402 has the glass transition temperature in the above range, durability of the high refractive adhesive layer 402 may be excellent.

The high refractive adhesive layer 402 may have a creep value in a range of about 10% to about 40% at 60° C. In case that the creep value is in the above range, the high refractive adhesive layer 402 may resist external force and may not be deformed. In case that the creep value is less than 10%, flexibility of the high refractive adhesive layer 402 may decrease during a folding operation, and in case that the creep value exceeds 40%, restoring force of the high refractive adhesive layer 402 may decrease.

The high refractive adhesive layer 402 may have a recovery value in a range of about 70% to about 80% at −20° C. In case that the recovery value is in the above range, the high refractive adhesive layer 402 may have excellent restoring force even in a low temperature environment.

The creep value as used herein may be a strain of a target sample in case that a shear stress of 2000 Pa is applied to the target sample for 10 minutes at a corresponding temperature. In case that shear stress is applied to the target sample for a specific time and removed in a creep experiment, a phenomenon in which the deformed target sample is recovered may be called recovery, and a recovery may be a strain value of the target sample recovered for 10 minutes after shear stress of 2000 Pa is applied to the target sample for 10 minutes and removed. After an adhesive layer sample having a diameter of 8 mm and a thickness of 800 μm is attached to a parallel plate made of stainless steel, a creep value and a recovery value of the adhesive layer sample may be obtained through an evaluation using a DHR device (whose loading force is 1 N and axial force is 1.0 N) available from TA Instruments. The adhesive layer sample is stabilized for 60 seconds after a temperature is raised to 60° C., a creep of the adhesive layer sample is measured by applying shear stress of 2000 Pa to the adhesive layer sample for 10 minutes, and a recovery of the adhesive layer sample is measured for 10 minutes after the shear stress is removed.

The high refractive adhesive layer 402 may include an ultraviolet absorber. The ultraviolet absorber may absorb ultraviolet (UV) having a wavelength region in a range of about 300 nm to about 380 nm.

The ultraviolet absorber may include a light-absorbing dye absorbing light. For example, the ultraviolet absorber may include a benzotriazole-based light-absorbing dye, a benzophenone-based light-absorbing dye, a salicylic acid-based light-absorbing dye, a salicylate-based light-absorbing dye, a cyanoacrylate-based light-absorbing dye, a cinnamate-based light-absorbing dye, an oxanilide-based light-absorbing dye, a polystyrene-based light-absorbing dye, a polyferrocenylsilane-based light-absorbing dye, a methine-based light-absorbing dye, an azomethine-based light-absorbing dye, a triazine-based light-absorbing dye, a para-aminobenzoic acid-based light-absorbing dye, a cinnamic acid-based light-absorbing dye, an urocanic acid-based light-absorbing dye, or a combination thereof, but not limited thereto.

The polarizing film 210 may be disposed on the high refractive adhesive layer 402. Since the high refractive adhesive layer 402 has both a planarization function and an adhesion function, the polarizing film 210 may be disposed directly on the high refractive adhesive layer 402.

The specification may provide a composition for an adhesive layer including the above-described aromatic monomer, aliphatic monomer, xylene resin, sulfide aromatic compound, and inorganic particles.

In case that the composition for an adhesive layer is photocured or thermally cured, an organic material layer having the above-described physical properties may be obtained.

In the above-described functional group, “substituted or unsubstituted” may refer to being substituted or unsubstituted with one or more substituents selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, an alkoxy group, a hydrocarbon ring group, an aryl group, and a heterocyclic group. Each of the above-described substituents may be substituted or unsubstituted. For example, a biphenyl group may be an aryl group or a phenyl group.

Examples of the halogen atom as used herein may include a fluorine atom, a chlorine atom, a bromine atom, or an iodine atom.

The alkyl group as used herein may be a straight chain alkyl group, a branched chain alkyl group, or a cyclic alkyl group. The number of carbon atoms of the alkyl group is 1 or more and 50 or less, 1 or more and 30 or less, 1 or more and 20 or less, 1 or more and 10 or less, or 1 or more and 6 or less. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldodecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-icosyl group, a 2-ethylicosyl group, a 2-butylicosyl group, a 2-hexylicosyl group, a 2-octylicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and the like, but are not limited thereto.

The aryl group as used herein may be any functional group or substituent derived from an aromatic hydrocarbon ring. The aryl group may be a monocyclic aryl group or a polycyclic aryl group. The number of carbon atoms forming a ring in the aryl group may be 6 or more and 30 or less, 6 or more and 20 or less, or 6 or more and 15 or less. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, and the like, but are not limited thereto.

The heteroaryl group as used herein may include one or more of B, O, N, P, Si, and S as heteroatoms. In case that the heteroaryl group includes two or more heteroatoms, the two or more heteroatoms may be the same as or different from each other. The heteroaryl group may be a monocyclic heterocyclic group or a polycyclic heterocyclic group. The number of carbon atoms forming a ring in the heteroaryl group may be 2 or more and 30 or less, 2 or more and 20 or less, or 2 or more and 10 or less. Examples of the heteroaryl group may include a thiophene group, a furan group, a pyrrole group, an imidazole group, a triazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilol group, a dibenzofuran group, and the like, but are not limited thereto.

The (meth)acrylate as used herein may be acrylate or methacrylate.

Hereinafter, Examples will be described in more detail through several experimental Examples.

### <Preparation of Composition for High Refractive Adhesive Layer>

A composition of Example 1 was prepared by mixing an aromatic monomer (50 wt %), an aliphatic monomer (20 wt %), a xylene resin (15 wt %), a sulfide aromatic compound (13 wt %), and inorganic particles (2 wt %) with each other.

Two aromatic monomers were used: 2-(phenyl) thioethyl acrylate was used as a first aromatic monomer, and o-phenylbenzyl acrylate was used as a second aromatic monomer, and a weight ratio between the first aromatic monomer and the second aromatic monomer was 2:1.

Three aliphatic monomers were used: a first aliphatic monomer was 2-{2-[(2-ethylhexyl)oxylethoxy} ethyl acrylate (DEHEA), a second aliphatic monomer was 2-ethylhexyl acrylate, and a third aliphatic monomer was 4-hydroxybutyl acrylate. A weight ratio between the first aliphatic monomer, the second aliphatic monomer, and the third aromatic monomer was 9:2:1.

The following Formula 1-1 was used as the xylene resin:

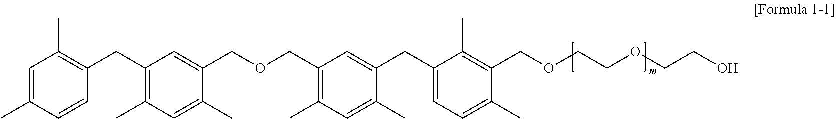

In Formula 1-1, m may be an integer of 1 to 100.

1,2-bis(phenylthio) ethane was used as the sulfide aromatic compound, and zirconium oxide was used as the inorganic particles.

A composition of Comparative Example 1 was prepared by excluding the three aliphatic monomers from the composition of Example 1 and changing a content of the aromatic monomer to 70 wt %. A weight ratio between the two aromatic monomers is the same as that in Example 1.

### <Formation and Evaluation of High Refractive Adhesive Layer>

High refractive adhesive layers were formed by applying the compositions of Example 1 and Comparative Example 1 to adherends using inkjet printing or Y-map coating and UV-curing the compositions.

The formed high refractive adhesive layers were evaluated and shown in Table 1.

TABLE 1

| | | Example 1 | Comparative Example 1 |
|---|---|---|---|
| at −20° C. | G′ (MPa) | 1.672345 | 1.21287 |
| | G″ (MPa) | 5.437105 | 3.45025 |
| | Tan delta | 3.25224 | 2.844625 |
| at 25° C. | G′ (MPa) | 0.018893 | 0.018871 |
| | G″ (MPa) | 0.008695 | 0.002541 |
| | Tan delta | 0.460209 | 0.134637 |
| at 60° C. | G′ (MPa) | 0.012477 | 0.019447 |
| | G″ (MPa) | 0.001769 | 0.00041 |
| | Tan delta | 0.141838 | 0.021009 |
| Tg (° C.) | | −20.387 | −20.302 |
| at 60° C. | Creep (%) | 18.535 | 9.873 |
| | Recovery (%) | 98.555 | 98.055 |
| at −20° C. | Recovery (%) | 87 | 67 |

| | | |
|---|---|---|
| Reliability | G | NG |

Referring to Table 1, it can be seen that a storage modulus, a loss modulus, and a viscoelastic ratio at −20° C. are higher in Example 1 than in Comparative Example 1. Even at a low temperature, the viscoelastic ratio of the high refractive adhesive layer of Example 1 is high, such that adhesive strength of the high refractive adhesive layer is excellent, and the storage modulus and the loss modulus of the high refractive adhesive layer of Example 1 are high, such that a crack may be prevented even during folding. A creep value of the high refractive adhesive layer of Example 1 at 60° C. is 10% or more, such that the high refractive adhesive layer may be sufficiently flexible even during a folding operation, and a recovery of the high refractive adhesive layer of Example 1 at −20° C. is 80% or more, such that permanent deformation of the high refractive adhesive layer after folding may be small. The high refractive adhesive layer of Example 1 received a G (Good) rating in a reliability evaluation.

On the other hand, the high refractive adhesive layer of Comparative Example 1 showed a low storage modulus and loss modulus at a low temperature, such that a delamination defect occurred. A creep value of the high refractive adhesive layer of Comparative Example 1 at 60° C. was less than 10%, such the high refractive adhesive layer may not be sufficiently deformed during a folding operation, and a recovery of the high refractive adhesive layer of Comparative Example 1 at −20° C. was less than 70%. The high refractive adhesive layer of Comparative Example 1 received a NG (Not Good) rating in a reliability evaluation.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a display panel including a light emitting element;
a low refractive pattern disposed on the display panel and including an opening overlapping the light emitting element in a thickness direction of the display panel; and
a high refractive adhesive layer disposed on the low refractive pattern and the display panel and including inorganic particles,
wherein the high refractive adhesive layer includes 1 wt % to 3 wt % of the inorganic particles based on a total weight of the high refractive adhesive layer.

2. The display device of claim 1, further comprising:
a polarizing film disposed on the high refractive adhesive layer.

3. The display device of claim 2, wherein the high refractive adhesive layer is in contact with the polarizing film.

4. The display device of claim 1, wherein
the low refractive pattern has a refractive index in a range of about 1.45 to about 1.55, and
the high refractive adhesive layer has a refractive index in a range of about 1.55 to about 1.65.

5. The display device of claim 1, wherein the inorganic particles are at least one of zirconium oxide (ZrO₂), titanium oxide (TiO₂), aluminum oxide (Al₂O₃), and silicon oxide (SiO₂).

6. The display device of claim 5, wherein the inorganic particles are dispersed in the high refractive adhesive layer.

7. The display device of claim 1, wherein the high refractive adhesive layer further includes an aromatic monomer and an aliphatic monomer.

8. The display device of claim 7, wherein the aromatic monomer includes a first aromatic monomer and a second aromatic monomer different from each other.

9. The display device of claim 7, wherein the aliphatic monomer includes a first aliphatic monomer, a second aliphatic monomer, and a third aliphatic monomer different from each other.

10. The display device of claim 7, wherein the high refractive adhesive layer further includes a xylene resin and a sulfide aromatic compound.

11. The display device of claim 10, wherein the high refractive adhesive layer includes about 40 wt % to about 80 wt % of the aromatic monomer, about 10 wt % to about 30 wt % of the aliphatic monomer, about 10 wt % to about 25 wt % of the xylene resin, about 10 wt % to about 20 wt % of the sulfide aromatic compound, and about 1 wt % to about 3 wt % of the inorganic particles based on the total weight of the high refractive adhesive layer.

12. The display device of claim 1, wherein
the high refractive adhesive layer has a storage modulus in a range of about 1.0 MPa to about 10 MPa at −20° C.,
the high refractive adhesive layer has a loss modulus in a range of about 3.5 MPa to about 10 MPa at −20° C., and
the high refractive adhesive layer has a viscoelastic ratio in a range of about 2.9 to about 6 at −20° C.

13. The display device of claim 1, wherein the high refractive adhesive layer has a glass transition temperature (Tg) in a range of about −30° C. to about −10° C.

14. The display device of claim 1, wherein the high refractive adhesive layer has a creep value in a range of about 10% to about 40% at 60° C.

15. The display device of claim 1, wherein the high refractive adhesive layer has a recovery value of greater than or equal to about 70% at −20° C.

16. The display device of claim 2, further comprising:
a touch sensor layer disposed between the display panel and the low refractive pattern,
wherein the high refractive adhesive layer is in contact with the touch sensor layer and the polarizing film.

17. The display device of claim 1, wherein the low refractive pattern has a tapered shape in a cross-sectional view.

18. A composition for an adhesive layer, comprising:
a first aromatic monomer and a second aromatic monomer different from each other;
a first aliphatic monomer, a second aliphatic monomer, and a third aliphatic monomer different from each other; and
inorganic particles including at least one of zirconium oxide (ZrO₂), titanium oxide (TiO₂), aluminum oxide (Al₂O₃), and silicon oxide (SiO₂),
wherein the inorganic particles are included in an amount of 1 wt % to 3 wt % based on a total weight of the composition for the adhesive layer.

19. The composition for an adhesive layer of claim 18, wherein
a molecular weight of the first aromatic monomer is less than a molecular weight of the second aromatic monomer,
a content of the first aromatic monomer is higher than a content of the second aromatic monomer,
a molecular weight of the first aliphatic monomer is greater than a molecular weight of the second aliphatic monomer and a molecular weight of the third aliphatic monomer,
the molecular weight of the second aliphatic monomer is greater than the molecular weight of the third aliphatic monomer,
a content of the first aliphatic monomer is higher than a content of the second aliphatic monomer and a content of the third aliphatic monomer, and
the content of the second aliphatic monomer is higher than the content of the third aliphatic monomer.

20. The composition for an adhesive layer of claim 18, further comprising:
a xylene resin and a sulfide aromatic compound.

21. An electronic device comprising:
a display device comprising a display panel including a light emitting element;
a low refractive pattern disposed on the display panel and including an opening overlapping the light emitting element in a thickness direction of the display panel; and
a high refractive adhesive layer disposed on the low refractive pattern and the display panel and including inorganic particles,
wherein the high refractive adhesive layer includes 1 wt % to 3 wt % of the inorganic particles based on a total weight of the high refractive adhesive layer.
